(19) United States
(12) Patent Application Publication
(10) Pub. No.: US 2008/0299739 A1
(43) Pub. Date: Dec. 4, 2008

(54) METHOD OF MANUFACTURING SEMICONDUCTOR DEVICE

(75) Inventors: Kazutaka YOSHIZAWA, Kawasaki (JP); Toru ANEZAKI, Kawasaki (JP); Katsuaki OOKOSHI, Kawasaki (JP); Teruki MORISHITA, Kawasaki (JP); Hajime WADA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/118,245

(22) Filed: May 9, 2008

(30) Foreign Application Priority Data
May 31, 2007 (JP) 2007-145330

(51) Int. Cl. H01L 21/76

(52) U.S. Cl. 438/424; 257/E21.54

(57) ABSTRACT

According to an aspect of an embodiment, a method of manufacturing a semiconductor device has forming a first insulating film over a rear surface of a plurality of silicon substrates, annealing the plurality of silicon substrates to degas the oxide species in the first insulating film, and oxidizing the surface of the plurality of silicon substrates in a batch process after annealing the silicon substrates.

### BACKGROUND

This technique relates to a method for manufacturing a semiconductor device, and more particularly relates to a method for manufacturing a semiconductor device in which an insulating film for suppressing warping of a silicon substrate is formed above a rear surface thereof.

In order to improve performance of a semiconductor integrated circuit device (IC), the size of a MOS transistor, which is a constituent element thereof, has been reduced, and hence the degree of integration has been improved. Concomitant with the improvement of the degree of integration, the number of layers of a multilayer interconnection structure has also been increased. In order to increase the number of chips obtained from one silicon wafer, the wafer size tends to be increased, and at the present time, a 12-inch wafer is most widely used.

When layers of a multilayer interconnection structure are formed above a silicon wafer surface with at least one interlayer insulating film interposed therebetween, due to the tensile stress of the interlayer insulating film, the rear surface side of the wafer may be convexly warped in some cases. As the wafer size is increased, the influence caused by warping of the wafer is also increased.

According to Japanese Laid-open Patent Publication No. 2005-26404, it has been disclosed that after a first film is formed on a front surface side of a semiconductor wafer, and the warpage thereof is then measured, second films are simultaneously formed at the front and the rear surface sides of the semiconductor wafer, followed by selectively removing a part or the entire of the second film provided at the rear surface side of the semiconductor wafer, and at this stage, the amount of the second film at the rear surface side to be removed is adjusted in accordance with the warpage.

An element isolation region formed by local oxidation of silicon (LOCOS) includes a bird beak portion which decreases an active area, and hence as a result, the improvement of the degree of integration is prevented. Accordingly, instead of LOCOS, shallow trench isolation (STI) has been widely used.

The element isolation region by STI is formed as described below. A silicon substrate surface is thermal-oxidized to form a buffer silicon oxide film, and a silicon nitride film is further formed thereon by chemical vapor deposition (CVD). Subsequently, the silicon nitride film and the silicon oxide film are etched to form an aperture pattern corresponding to the element isolation regions. By using the patterned silicon nitride film as a mask, the silicon substrate is etched to form element isolation grooves. By the element isolation groove, the active region is defined. After a liner such as a thermal-oxidized film is formed, whenever necessary, on the surface of the element isolation groove, the element isolation groove is filled with a silicon oxide film by high density plasma (HDP) CVD or the like. By using the silicon nitride film as a stopper, the silicon oxide film on the silicon nitride film is removed by chemical mechanical polishing (CMP). The surface of the wafer is planarized by CMP. The exposed silicon nitride film is removed by hot phosphoric acid, and the buffer silicon oxide film is removed by diluted hydrofluoric acid, so that the surface of the active region is exposed.

Japanese Laid-open Patent Publication No. 2006-4989 has disclosed that after silicon oxide films are formed on a front and a rear surface of each silicon wafer by a thermal oxidation method, many silicon wafers thus processed are placed in a vertical furnace, and silicon nitride films and silicon oxide films are formed on the front and the rear surfaces of each of the above wafers using thermal CVD by a batch treatment, followed by removing the silicon oxide film on the front surface of each wafer by wet etching using diluted hydrofluoric acid. The silicon nitride film on the front surface of the wafer is a film used as an etching mask and also as a CMP stopper, and the silicon nitride film on the rear surface of the wafer is a film for suppressing warping. The silicon oxide film provided on the silicon nitride film on the rear surface of the wafer functions as a protective film that allows the silicon nitride film on the rear surface of the wafer to remain when the silicon nitride film on the front surface of the wafer is removed by hot phosphoric acid.

After STI is formed, the surface of the active region is thermal-oxidized to form a sacrifice silicon oxide film for ion implantation, and ion implantations for well formation, channel stopper formation, and threshold adjustment are then performed in accordance with properties of each transistor. After the ion plantations, the sacrifice silicon oxide film is removed by etching. The surface of the active region is again thermal-oxidized to form a gate silicon oxide film. When transistors having different drive voltages are formed, gate silicon oxide films having different thicknesses are formed.

Logic semiconductor devices including rewritable non-volatile semiconductor memories form product fields, such as a complex programmable logic device (CPLD) and a field programmable gate array (FPGA), and their programmable features have already established large markets. As a typical example of the rewritable non-volatile semiconductor memory, a flash memory cell may be mentioned in which an insulation gate electrode of an NMOS transistor has a multilayer electrode structure including a tunnel insulating film, a floating gate electrode, an inter-gate insulating film, and a control gate electrode laminated to each other. The floating gate is charged and discharged for writing/erasing, and the channel is controlled by a voltage of the control gate electrode through the floating gate electrode; hence, the operating voltage is increased.

A logic circuit is formed of a CMOS circuit using an n-channel MOS transistor (NMOS) and a p-channel MOS transistor (PMOS). In logic semiconductor devices including non-volatile memories, in addition to a flash memory, a high voltage transistor for flash memory control, a low voltage transistor for high-performance logic circuit, and also a medium voltage transistor for external input are integrated on one semiconductor chip. Accordingly, the drive voltage of the CMOS circuit includes at least three types, that is, a high voltage, a medium voltage, and a low voltage.

International Patent Application Publication Pamphlet No. WO 2004/093192 and Japanese Laid-open Patent Publication No. 2005-142362 have disclosed a method for manufacturing 11 types of transistors, which include one flash memory cell; 8 types of MOS transistors, i.e., high and low-voltage, and low and high-threshold CMOS transistors; and 2 types of transistors, i.e., medium-voltage CMOS transistors for external input.

In transistor regions having different operating voltages, plural types of gate insulating films having different thicknesses are formed. When a thick gate silicon oxide film and a thin gate silicon oxide film are formed, for example, the thick gate silicon oxide film is first formed on the entire active region surface, and the thick gate silicon oxide film is the removed selectively in each region in which the thin gate silicon oxide film is to be formed. Subsequently, the thin gate silicon oxide film is formed. When gate oxide films having three different thicknesses are formed, the gate oxide film etching step and the subsequent gate oxide film formation step are each necessarily performed twice.

The gate electrode of the flash memory has the structure in which the control gate is provided on the floating gate with an ONO film (silicon oxide film/silicon nitride film/silicon oxide film) interposed therebetween. The floating gate is a gate electrode in an electrically floating state, is generally formed of polycrystalline silicon, and is patterned by performing an etching step twice.

### SUMMARY

According to an aspect of an embodiment, a method of manufacturing a semiconductor device has forming a first insulating film over a rear surface of a silicon substrate, annealing the silicon substrate to degas the oxide species in the first insulating film, and oxidizing the surface of the silicon substrate in a batch process after annealing the silicon substrate.

### BRIEF DESCRIPTION OF THE DRAWINGS

FIGS. 1A, 1B, 1C and 1G are each cross-sectional views of a semiconductor wafer showing a major step of a method for manufacturing a semiconductor device, according to a comparative example;

FIGS. 1E, 1F and 1G are each cross-sectional views of the semiconductor wafer showing a major step of the method for manufacturing a semiconductor device, according to the comparative example;

FIG. 2A is a cross-sectional view schematically showing the structure of a vertical furnace;

FIG. 2B is a cross-sectional view schematically showing the state in which oxide species get out of oxide layers, which is based on the consideration by the inventors of the present embodiment;

FIG. 3A is a cross-sectional view of a vertical furnace illustrating a first preliminary experiment;

FIGS. 3B and 3C are graphs showing the average oxide film thickness and the standard deviation (sigma) thereof, respectively, which are obtained from test wafers used in the first preliminary experiment;

FIGS. 4A and 4B are each cross-sectional views of a vertical furnace illustrating a second preliminary experiment;

FIGS. 4C and 4D are graphs showing the average oxide film thickness and the standard deviation (sigma) thereof, respectively, which are obtained from test wafers used in the second preliminary experiment; and

FIGS. 5A to 5T are each cross-sectional views of a semiconductor wafer showing a major step of a method of manufacturing a semiconductor device, according to an example.

### DESCRIPTION OF THE PREFERRED EMBODIMENTS

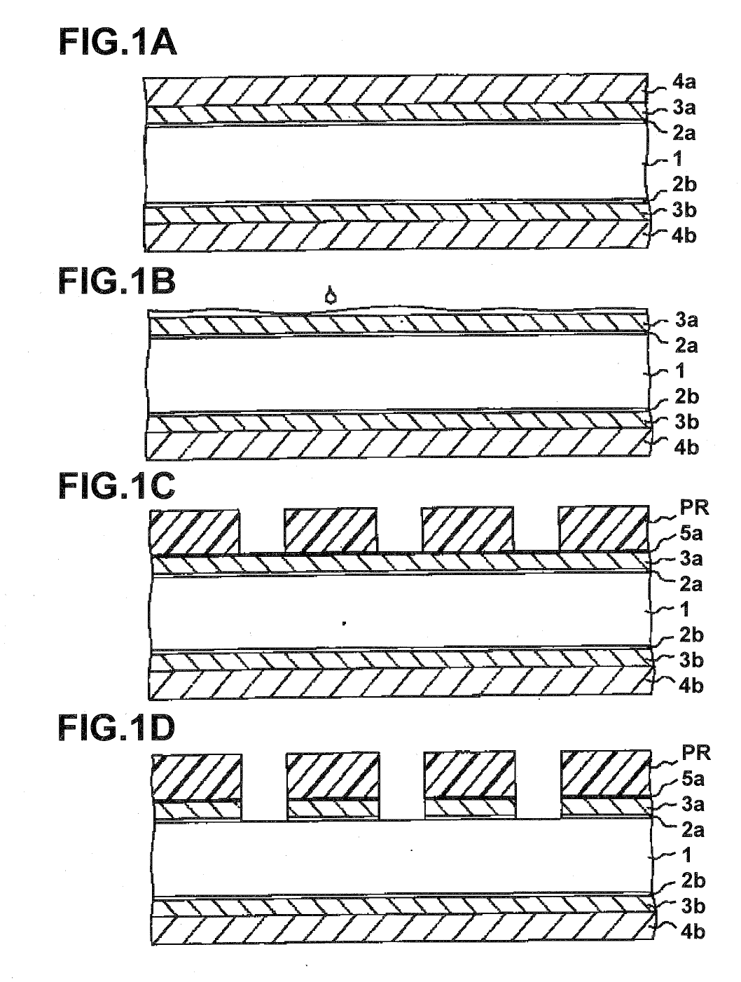

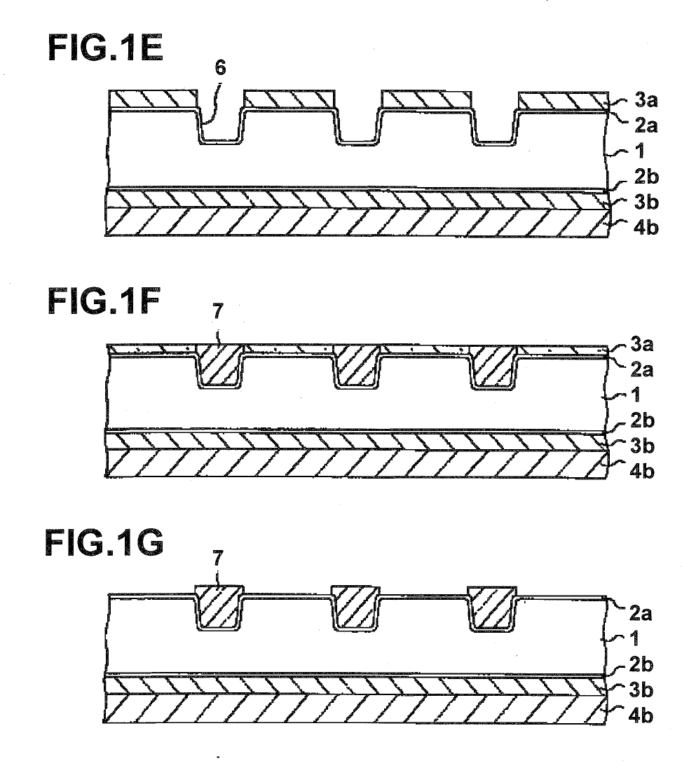

Prior to description of an example, a comparative example will be described with reference to FIGS. 1A to 1G.

As shown in FIG. 1A, after a front and a rear surface of a silicon wafer (substrate) 1 are thermal-oxidized to form buffer silicon oxide films 2a and 2b, silicon nitride films 3a and 3b are formed thereon by chemical vapor deposition (CVD), and further, silicon oxide films 4a and 4b subsequently formed using tetraethoxysilane (TEOS) also by CVD. In this case, the suffix “a” indicates a constituent element at the front surface side, and the suffix “b” indicates a constituent element at the rear surface side.

As shown in FIG. 1B, while the silicon wafer 1 is rotated, diluted hydrofluoric acid is dripped on the front surface of the silicon wafer 1, so that the TEOS silicon oxide film 4a at the front surface side is removed. The TEOS silicon oxide film 4b at the rear surface side of the silicon wafer 1 is not removed and still stays so as to cover the silicon nitride film 3b.

As shown in FIG. 1C, the surface of the silicon nitride film 3a exposed at the front surface side is oxidized by ashing using oxygen plasma, so that an oxide film 5 is formed. Since the surface of the silicon nitride film 3a is hydrophobic, when a photoresist pattern is formed thereon, the photoresist pattern is warped as if the side surface thereof is pushed up from the bottom side. When the oxide film 5 is formed on the surface of the silicon nitride film 3a, the surface is changed to hydrophilic, and as a result, the warpage of the side surface of the photoresist pattern can be reduced. A photoresist pattern PR is formed on the silicon nitride film 3a provided with the oxide film 5 thereon. Aperture portions in the photoresist pattern PR correspond to element isolation grooves.

As shown in FIG. 1D, the oxide film 5, the silicon nitride film 3a, and the silicon oxide film 2a are patterned by anisotropic etching using the photoresist pattern PR as an etching mask, so that parts of the buffer silicon oxide film 2a, silicon nitride film 3a, and oxide film 5, which form a hard mask covering active regions, are allowed to remain. In addition, actually, part of the silicon oxide film 2a is not etched away and is allowed to remain. Subsequently, the photoresist pattern PR is removed.

As shown in FIG. 1E, the silicon substrate is etched using the silicon nitride film 3a as an etching mask to form the element isolation grooves. After the element isolation grooves are formed, the silicon surface is dry-oxidized at a high temperature in the range of 1,000 to 1,200° C., such as 1,100° C. A silicon surface exposed in the element isolation groove is oxidized, so that a silicon oxide film 6 is formed. In this oxidizing atmosphere, the exposed silicon surface is not only oxidized but the silicon surface below the silicon nitride film 3a is also oxidized through the buffer silicon oxide film 2a; hence, as a result, the silicon oxide film 6 is formed so as to cover the corner portions of the active regions. This dry oxidation is performed by a batch treatment using a vertical furnace.

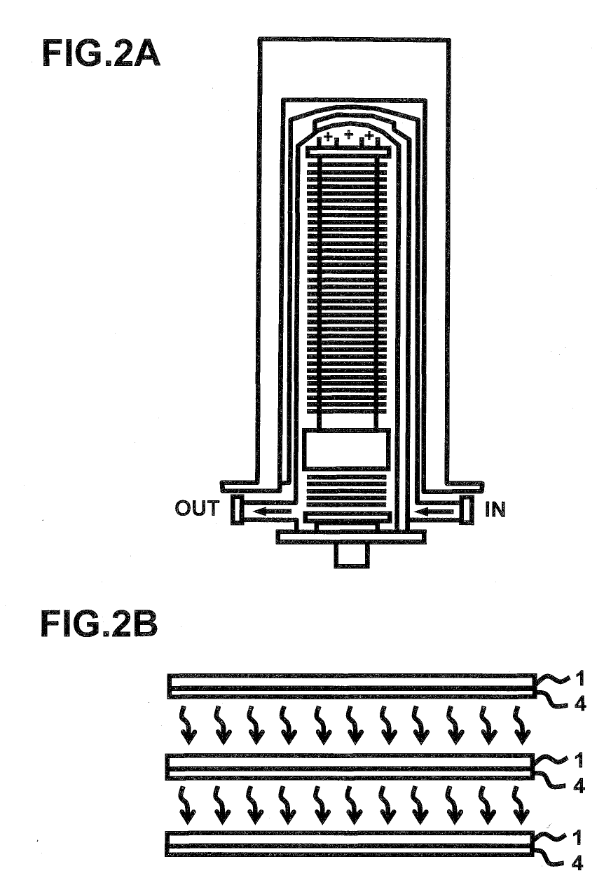

FIG. 2A is a cross-sectional view showing the structure of a vertical furnace used for the process. This vertical furnace is a furnace commercially available under the trade name QUIXACE (registered trademark) manufactured by Hitachi Kokusai Electric Inc. In this furnace, 120 wafers can be disposed at approximately 8 mm spatial intervals. An oxidizing atmospheric gas is introduced from a gas inlet IN, is then supplied in a reaction chamber from an upper portion of the vertical furnace, and is discharged from a gas outlet OUT.

As shown in FIG. 1F, an insulating film 7, such as a silicon oxide film, is deposited by high density plasma (HDP) CVD to have a thickness approximately ranging from 350 nm to 500 nm, so that the element isolation grooves are filled. An excess part of the insulating film 7 is removed by polishing using chemical mechanical polishing (CMP). In this step, the silicon nitride film 3a functions as a stopper.

As shown in FIG. 1G, the silicon nitride film 3a is removed by phosphoric acid boiling. Since being covered with the silicon oxide film 4b, the silicon nitride film 3b provided at the rear surface side is not removed. Subsequently, the buffer silicon oxide film 2a is removed by diluted hydrofluoric acid.

The thickness of the silicon oxide film 6, shown in FIG. 1E, formed by the rounding oxidation has abnormal distribution. This phenomenon was not observed when an 8-inch (200 mm) wafer having a smaller size and a 12-inch wafer having a large diameter were processed by wet oxidation at a temperature of approximately 900° C. The non-uniformity of the thickness distribution caused by the rounding oxidation indicates that the rounding of the corner portions of the active region is not uniformly performed. When the rounding is insufficiently performed, the electric field concentration cannot be sufficiently reduced, and when the rounding is excessively performed, the area of the effective active region having a flat surface is decreased.

The inventors of the present embodiment have considered the reasons of this abnormal thickness distribution of the oxide film. The rounding oxidation step was performed using the vertical furnace shown in FIG. 2A. In the vertical furnace, 120 wafers of 12 inches in diameter can be placed.

FIG. 2B schematically shows a plurality of wafers 1 to be processed by a batch treatment. The TEOS silicon oxide film 4b is formed on the rear surface of each wafer 1 and faces the front surface of the wafer 1 disposed thereunder. The TEOS silicon oxide film 4 may contain oxide species, such as moisture, in some cases. Hence, it may be believed that when heating is performed in dry oxidation, the oxide species, such as moisture, may get out of the TEOS silicon oxide film 4 by evaporation or the like. The distance between the rear surface of one wafer and the front surface of a wafer provided thereunder is less than 8 mm, and the diameter of the wafer is approximately 30 cm. Hence, the oxide species, such as moisture, out of the rear surface of the wafer may be trapped in the front surface of the wafer provided thereunder before the oxide species reaches the outside of the edge portion of the wafer and may perform oxidation in some cases. Accordingly, the following experiment was carried out.

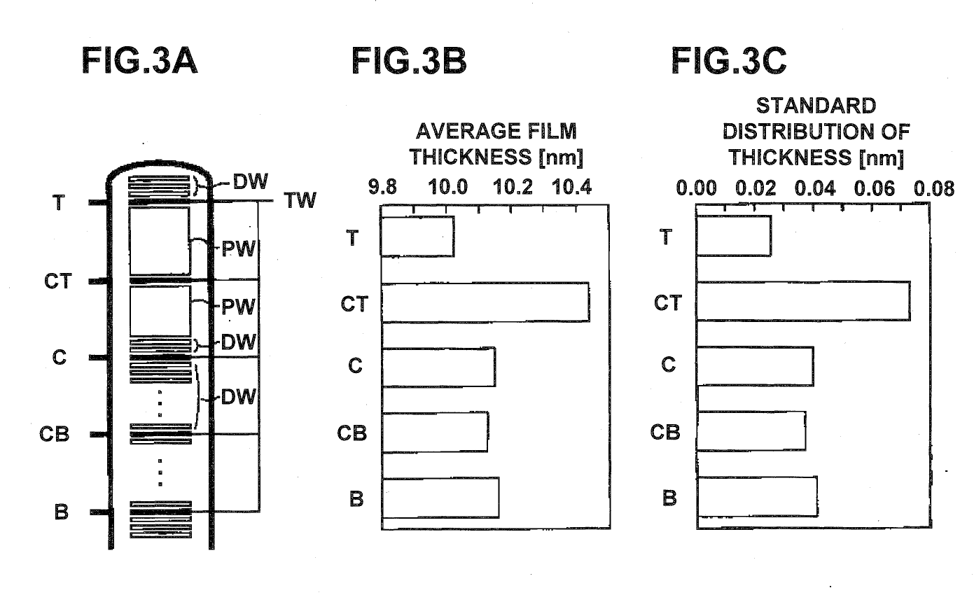

In FIGS. 3A and 3B, a first preliminary experiment and the results thereof are shown.

As shown in FIG. 3A, test bare wafers TW were disposed at a top T, a center C, a bottom B, a middle CT between the center and the top, and a middle CB between the center and the bottom; product wafers provided with the element isolation grooves formed by the steps shown in FIGS. 1A to 1E were disposed at a region PW between T and CT and a region PW from CT to C; and dummy wafers provided with oxide films thereon were disposed in the other remaining regions including a region above T and a region below B. Although oxide films were formed on the dummy wafer while it was repeatedly used, a TEOS oxide film and STI were not formed.

The product wafers PW were present above the test wafer at the position CT, and the dummy wafers were present above the test wafers at the positions T, C, CB, and B. Rounding dry oxidation was performed on the wafers thus disposed at a temperature of 1,000 to 1,200° C.

FIG. 3B shows the average film thickness of a silicon oxide film formed by thermal oxidation at a wafer surface, and FIG. 3C shows the standard deviation (sigma) of thickness distribution of the silicon oxide film formed by thermal oxidation at the wafer surface. The vertical axis indicates the position of the test wafer in the vertical furnace. The value at the position CT is a measurement value of the test wafer disposed immediately under the product wafer, and other values are measured values of the test wafers disposed immediately under the dummy wafers. The dummy wafers are present above and under the test wafers only at the positions C, CB and B. Hence, it is believed that variation in measured values of the above test wafers may inevitably occur. The test wafer disposed immediately under the product wafer apparently has a large average oxide film thickness and a large standard deviation of the film thickness. The reason for this is believed that oxide species get out of the TEOS oxide film provided on the rear surface of the wafer and then non-uniformly oxidize the surface of the wafer disposed thereunder.

In order to prevent the oxide species out of the TEOS silicon oxide film from oxidizing the front surface of an adjacent wafer to form a thicker oxide layer, the oxide species may be removed beforehand from the TEOS silicon oxide film.

Hereinafter, second, third, and fourth preliminary experiments and the measurement results thereof will be described. It was intended to degas the oxide species from the TEOS silicon oxide film by annealing performed under the state in which the TEOS silicon oxide film remains only above the rear surface of the silicon wafer and STI is formed at the front surface side (rounding oxidation is not performed) by the steps shown in FIGS. 1A to 1E. In the second preliminary experiment, annealing was performed at 900° C. for 60 minutes, 900° C. for 90 minutes, and 950° C. for 30 minutes. In the third preliminary experiment, annealing was performed at 800° C. for 30 minutes, 850° C. for 30 minutes, and 900° C. for 30 minutes.

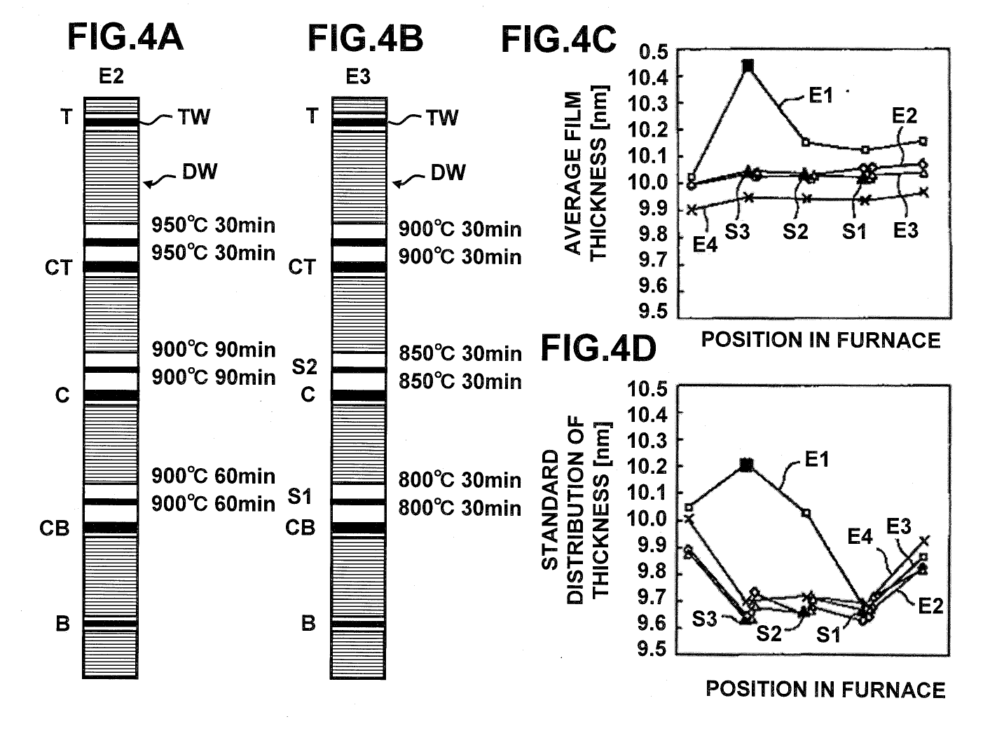

As shown in FIG. 4A, in the second preliminary experiment, bare test wafers TW were disposed at the positions T, CT, C, CB, and B, and in addition, a bare test wafer provided between product wafers annealed at 950° C. for 30 minutes, a bare test wafer provided between product wafers annealed at 900° C. for 90 minutes, and a bare test wafer provided between product wafers annealed at 900° C. for 60 minutes were disposed above the test wafers at the positions CT, C, and CB, respectively. At the other positions, dummy wafers were disposed.

As shown in FIG. 4B, in the third preliminary experiment, bare test wafers TW were disposed at the positions T, CT, C, CB, and B, and in addition, a bare test wafer S3 provided between product wafers annealed at 900° C. for 30 minutes, a bare test wafer S2 provided between product wafers annealed at 850° C. for 30 minutes, and a bare test wafer S1 provided between product wafers annealed at 800° C. for 30 minutes were disposed above the test wafers at the positions CT, C, and CB, respectively. At the other positions, dummy wafers were disposed.

Furthermore, in the fourth preliminary experiment, dummy wafers were disposed at positions other than those at which bare test wafers were disposed.

In the second, third, and fourth preliminary experiments, rounding dry oxidation at a temperature of 1,000 to 1,200° C. was performed.

FIG. 4C shows the average film thickness of the test wafer, and FIG. 4D shows the standard deviation (sigma) of the thickness distribution of the test wafer. Reference numerals E1, E2, E3, and E4 indicate the measured values of the first, second, third, and fourth preliminary experiments, respectively. The measured values of the first preliminary experiment in FIGS. 3B and 3C are also shown for comparison purpose. The abnormal oxide film distribution was generated on the test wafer disposed under the product wafer.

Although it is naturally understood that the abnormal distribution was not observed in the fourth preliminary experiment in which the TEOS silicon oxide film is not present, the abnormal distribution of the oxide film thickness was not observed in the results of the second and the third preliminary experiments. The annealing temperatures for annealing the wafers used in the second preliminary experiment were 900 and 950° C., and the abnormal distribution of the oxide film thickness was not recognized. Even in the test wafers S1, S2, and S3 provided between the wafers processed by the annealing treatments performed at a lower temperature or for a shorter time, the abnormal distribution of the oxide film thickness was not observed. Hence, it is believed that by annealing performed at 800° C. for 30 minutes, degassing of the oxide species can be performed similar to that performed at a higher temperature for a longer time. It is also believed that even when the annealing time is decreased to 20 minutes, substantially effective degassing can be performed at a temperature of 800° C. or more. Hence, when the TEOS silicon oxide film is annealed at a temperature of 800° C. for 20 minutes or more, the oxide species can be degassed, and in the subsequent rounding oxidation, the abnormal distribution of the oxide film thickness may be suppressed. Although the upper limit of the annealing is not particularly limited, in a practical point of view, the annealing time and the annealing temperature may be 90 minutes and 950° C., respectively.

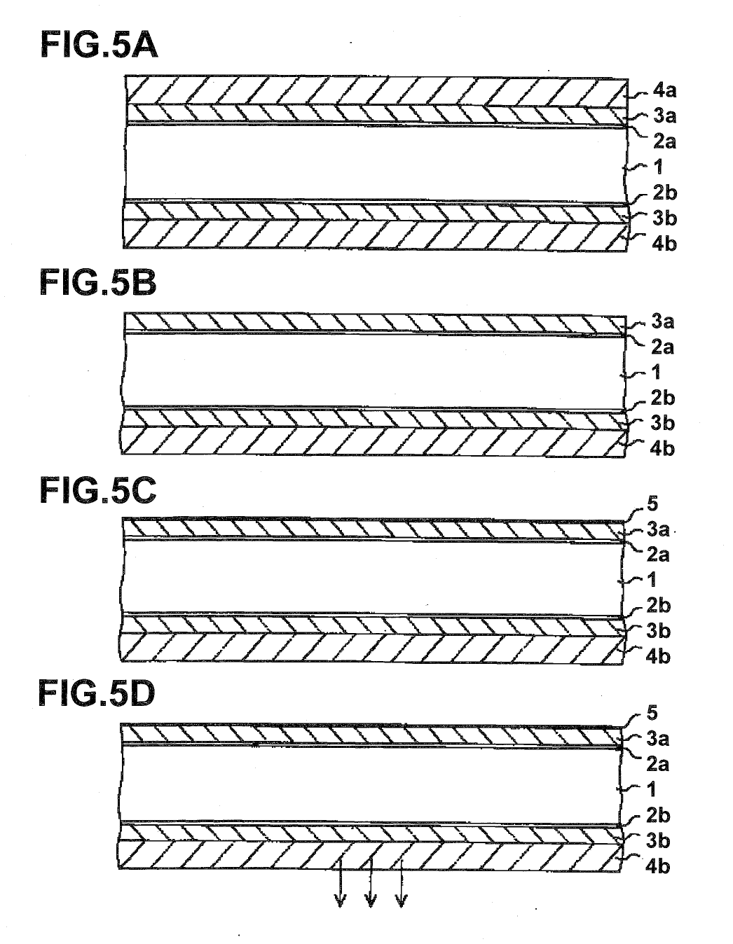

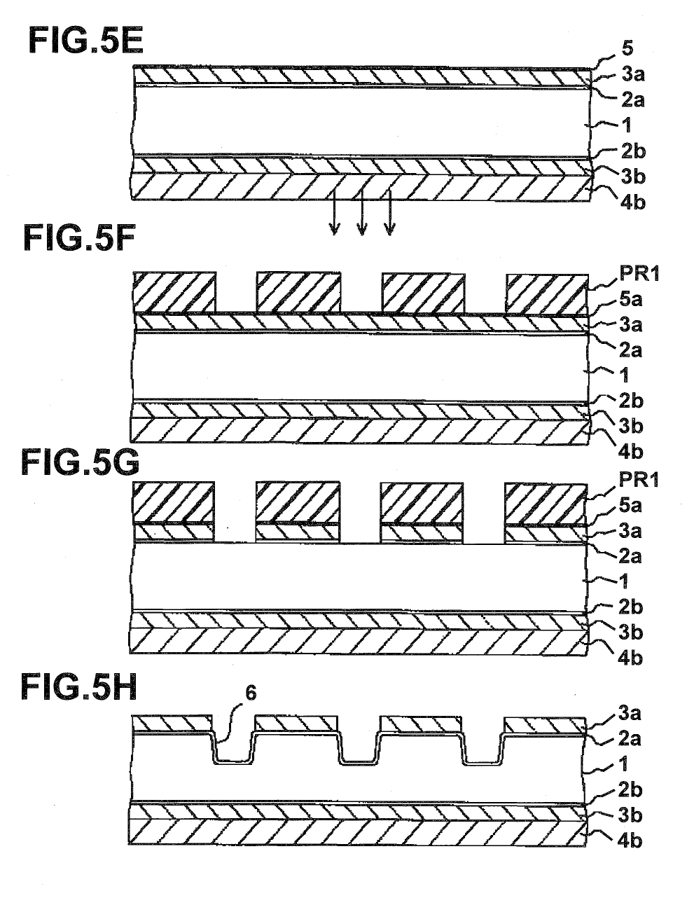

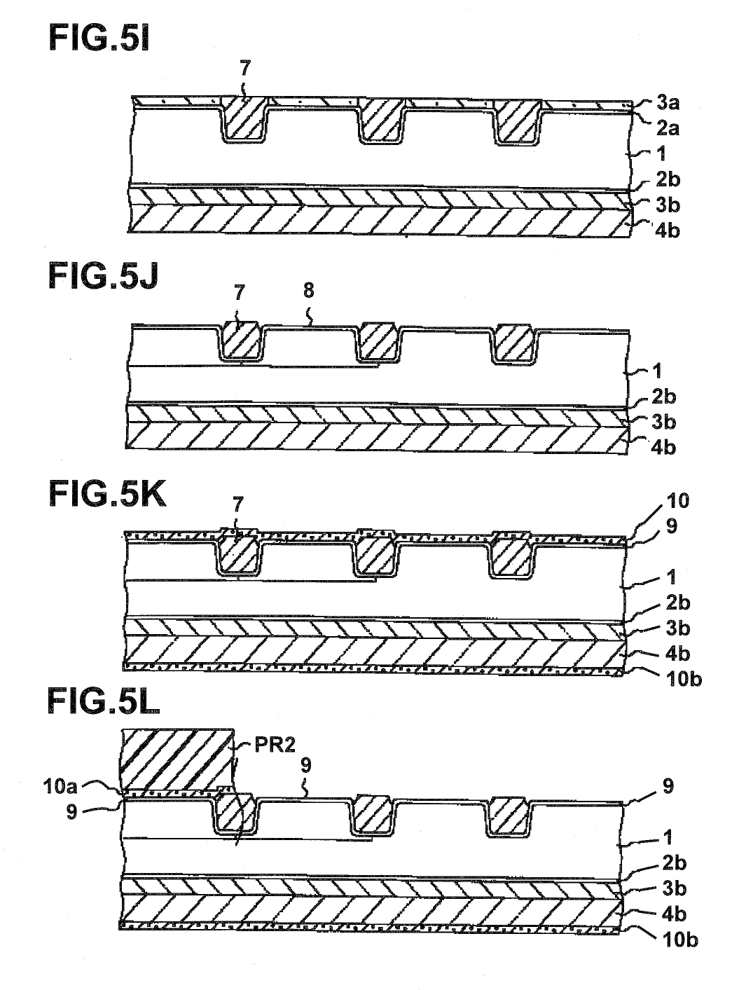

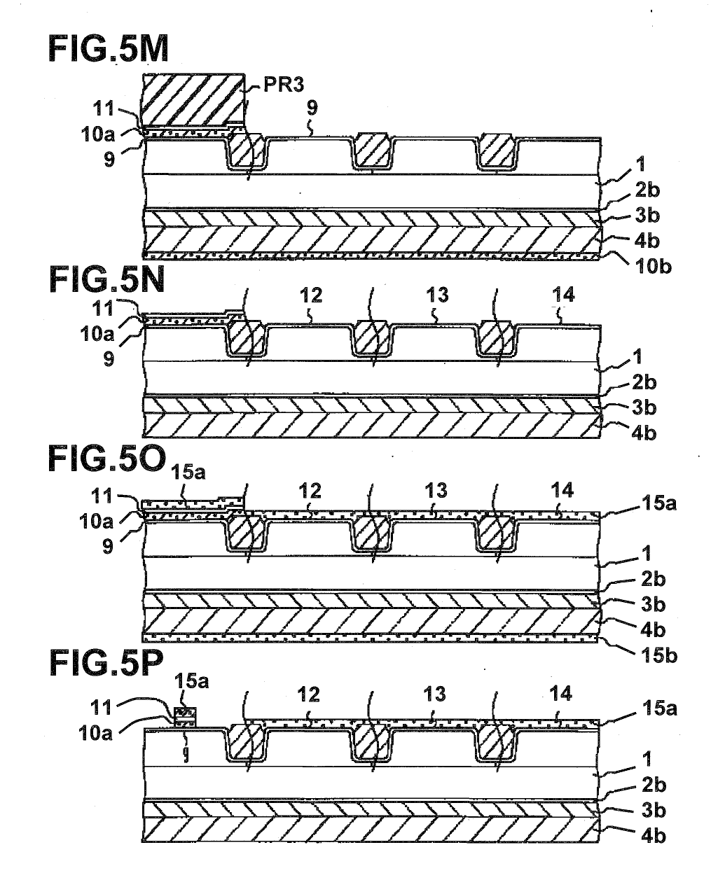

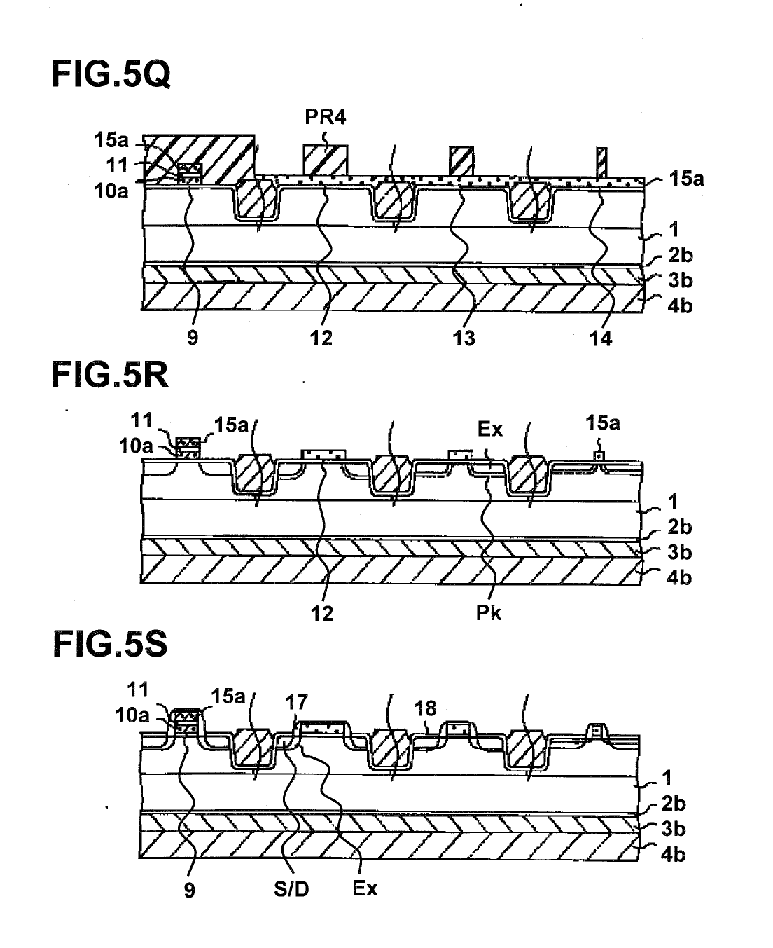

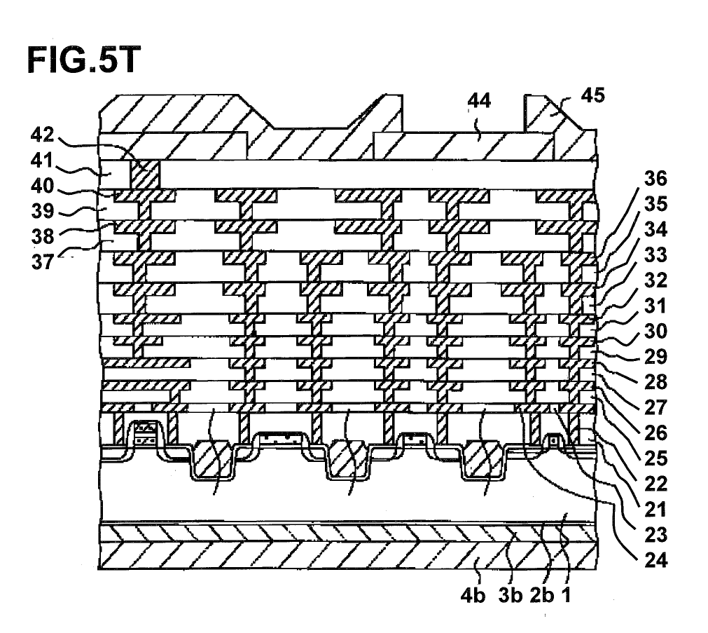

Hereinafter, with reference to FIGS. 5A to 5T, an example based on the experimental results will be described.

As shown in FIG. 5A, buffer silicon oxide films 2a and 2b are formed on the front and the rear surfaces of a silicon substrate 1, and silicon nitride films 3a and 3b are formed thereon, respectively, to have a thickness ranging from 80 nm to 120 nm by chemical vapor deposition (CVD). Silicon oxide films 4a and 4b are deposited on the silicon nitride films 3a and 3b to have a thickness ranging from 200 nm to 400 nm by CVD at 680° C. using tetraethoxysilane (TEOS).

As shown in FIG. 5B, while the silicon wafer 1 is rotated, diluted hydrofluoric acid is dripped on the front surface of the silicon wafer 1, so that the TEOS silicon oxide film 4a at the front surface side is removed. The TEOS silicon oxide film 4b at the rear surface side of the silicon wafer 1 is not removed and still stays to cover the silicon nitride film 3b.

As shown in FIG. 5C, the surface of the silicon nitride film 3a exposed at the front surface side is oxidized by ashing using oxygen plasma, so that an oxide film 5 is formed. Although the surface of the silicon nitride film 3a is hydrophobic, when the oxide film 5 is formed on the surface of the silicon nitride film 3a, the surface is changed to hydrophilic, and as a result, it is believed that the adhesion of a photoresist pattern can be improved. When a photoresist pattern is directly applied to a hydrophobic silicon nitride film, the side surface of the resist tends to curl due to the surface tension; however, because of the improvement in adhesion, it is believed that the above tendency is suppressed.

As shown in FIG. 5D, by performing atmospheric pressure dry annealing at 800° C. for 20 minutes or more in a N₂ atmosphere, oxide species, such as moisture, are removed from the TEOS silicon oxide film 4b by degassing.

Incidentally, the oxidation of the surface of the silicon nitride film 3a at the front surface side of the wafer and the degassing from the TEOS silicon oxide film 4b at the rear surface side of the wafer are not limited to the methods described above. As described below, a continuous treatment may be performed in the same chamber.

As shown in FIG. 5E, wet oxidation is performed at 750° C. in a N₂/O₂ atmosphere on the surface of the silicon nitride film 3a at the front surface side of the wafer, which corresponds to oxidation forming an oxide thickness of approximately 3 nm, followed by performing annealing at 800° C. for 20 minutes or more in a N₂ atmosphere, so that the oxide species, such as moisture, are degassed from the TEOS silicon oxide film 4b at the rear surface side of the wafer. It is intended to obtain an oxide film thickness equivalent to that obtained by the ashing; however, the thickness of the oxide film formed by ashing the SiN film cannot be directly measured. Hence, after the oxygen content of a test wafer in which a SiN film was oxidized by ashing was measured, the measured oxygen content was set as a target value, and the oxygen content of a test wafer in which a SiN film was wet-oxidized in a N₂/O₂ atmosphere was adjusted. An oxide film having a thickness of 3 nm is an oxide film formed by wet oxidation using a test wafer in a N₂/O₂ atmosphere in order to estimate the oxide amount. Hence, an oxide film having a thickness of 3 nm is not formed on the SiN film. The oxidation conditions may be set so that the oxidation amount is equivalent to that obtained by the ashing.

After the silicon nitride film and the TEOS silicon oxide film are formed, when degassing is performed for the TEOS silicon oxide film, in a subsequent thermal oxidation step, the oxide species can be suppressed from being degassed from the TEOS silicon oxide film, so that the uniformity in film thickness distribution can be prevented from being degraded. The uniformity in film thickness distribution can be basically prevented from being degraded when degassing is performed prior to the thermal oxidation step; however, after the TEOS silicon oxide film is deposited, when degassing is performed in the state in which the front and the rear surfaces of the silicon wafer are entirely covered with the silicon nitride films 3a and 3b, since the silicon surfaces of the silicon wafer are entirely covered with the silicon nitride films, no oxidation substantially occurs, and hence the properties of the silicon wafer can be more reliably ensured. As the steps performed after this degassing, various known steps may be used. For example, steps disclosed in the columns of “Best modes for carrying out the embodiment” of International Patent Application Publication Pamphlet No. W02004/093192 and Japanese Laid-open Patent Publication No. 2005-142362 may be used.

As shown in FIG. 5F, a photoresist pattern PR1 is formed on the silicon nitride film 3a provided with the oxide film 5 thereon. The aperture portions in the photoresist pattern PR1 correspond to element isolation grooves.

As shown in FIG. 5G, the oxide film 5, the silicon nitride film 3a, and the silicon oxide film 2a are patterned by anisotropic etching using the photoresist pattern PR1 as an etching mask, so that a hard mask covering active regions is formed. Subsequently, the photoresist pattern PR1 is removed.

As shown in FIG. 5H, the silicon wafer is etched to have a depth ranging from 250 nm to 350 nm using the silicon nitride film 3a as an etching mask, so that the element isolation grooves are formed. After the element isolation grooves are formed, the silicon surface is dry-oxidized at a high temperature of 1,000 to 1,200° C. An exposed silicon surface in the element isolation groove is oxidized, so that an oxide film 6 is formed. In this oxidizing atmosphere, the exposed silicon surface is not only oxidized, but the silicon surface under the silicon nitride film 3a is also oxidized through the buffer silicon oxide film 2a, thereby growing the silicon film 6 so as to cover the corner portions of the active regions.

As shown in FIG. 5I, an insulating film 7, such as a silicon oxide film, is deposited by high density plasma (HDP) CVD to have a thickness approximately ranging from 350 nm to 500 nm, so that the element isolation grooves are filled. An excess part of the insulating film 7 is removed by polishing using chemical mechanical polishing (CMP). In this step, the silicon nitride film 3a functions as a stopper.

As shown in FIG. 5J, the silicon nitride film 3a is removed by phosphoric acid boiling. Since being covered with the silicon oxide film 4b, the silicon nitride film 3b provided at the rear surface side is not removed. Subsequently, the buffer silicon oxide film 2a is removed by diluted hydrofluoric acid.

A sacrifice oxide film 8 is formed on the exposed silicon surface to have a thickness of approximately 10 nm, followed by performing ion implantations in a flash memory cell region and a high voltage transistor region, thereby forming a p-well of the flash memory and a p-well and an n-well of the high voltage transistor, each having a desired impurity distribution. Subsequently, the sacrifice oxide film 8 is removed by an aqueous hydrofluoric acid solution. In this figure, a flash memory region, a high voltage transistor region, a medium voltage transistor region, and a low voltage transistor region are shown from the left; however, the high voltage transistor region, the medium voltage transistor region, and the low voltage transistor region each include at least a NMOS region and a PMOS region, and in the above regions, the conductivity is opposite to each other.

As shown in FIG. 5K, a new tunnel oxide film 9 is formed to have a thickness of approximately 10 nm, and a phosphor-doped amorphous silicon film 10a is deposited over the entire surface including the tunnel oxide film 9 to have a thickness approximately ranging from 70 nm to 100 nm. An amorphous silicon film 10b is also deposited above the rear surface of the silicon wafer 1.

As shown in FIG. 5L, the flash memory region is covered with a photoresist pattern PR2, and the doped amorphous silicon film 10a in the region other than the flash memory region is removed by etching.

As shown in FIG. 5M, an ONO film 11 is deposited over the entire surface at the front surface side of the silicon wafer, and subsequently, ion implantations for well formation and threshold control are performed in the medium voltage transistor region and the low voltage transistor region. In addition, after the flash memory region is covered with a photoresist mask PR3, the ONO film 11 in the other region is removed by dry etching using a different gas, and the etching is stopped at part of the tunnel oxide film 9.

By using the same mask as described above, the silicon oxide film, such as the tunnel oxide film 9, remaining on the region other than the flash memory region is removed by an aqueous hydrofluoric acid solution. In addition, the doped amorphous silicon film 10b at the rear surface side of the silicon wafer is also removed.

As shown in FIG. 5N, a silicon oxide film 12, which is used for the high voltage transistor, having a thickness of approximately 15 nm is formed in an exposed active region surface by thermal oxidation. The ONO film 11 is hardly changed since the silicon nitride film inhibits the oxidation. The silicon oxide film 12 in the medium voltage and the low voltage transistor regions is removed by an aqueous hydrofluoric acid solution using a photoresist pattern. A silicon oxide film 13, which is used for the medium voltage transistor, having a thickness of approximately 7 nm is formed in an exposed active region by thermal oxidation. The thickness of the silicon oxide film 12 is also slightly increased. The silicon oxide film 13 in the low voltage transistor region is removed by an aqueous hydrofluoric acid solution using a photoresist pattern. A silicon oxide film 14, which is used for the low voltage transistor, having a thickness of approximately 1.5 nm is formed in an exposed active region by thermal oxidation. The thicknesses of the other silicon oxide films are also slightly increased.

As shown in FIG. 5O, a polycrystalline silicon film 15 having a thickness of approximately 100 nm is deposited on the entire silicon wafer by CVD. A polycrystalline silicon film 15a is deposited on the front surface side, and in addition, a polycrystalline silicon film 15b is also deposited on the rear surface side.

As shown in FIG. 5P, the polycrystalline silicon film 15b (and the TEOS silicon oxide film 4b) at the rear surface side of the silicon wafer is selectively removed. Subsequently, the polycrystalline silicon film 15a, the ONO film 11, and the doped amorphous silicon film 10a in the flash memory region are sequentially etched, so that a stack gate structure is formed. In the following figures, the case in which the polycrystalline silicon film 15b at the rear surface side is only removed is shown; however, the TEOS silicon oxide film 4b may also be removed together with the polycrystalline silicon film 15b.

As shown in FIG. 5Q, a photoresist pattern PR4 is formed which covers the flash memory region and which has the shape of a gate electrode in a logic region, and the polycrystalline silicon film 15a is etched, so that the gate electrodes are patterned.

As shown in FIG. 5R, by ion implantation using a photoresist pattern, desired extension regions Ex and pocket regions Pk are formed. In addition, since having the same conductivity type as that of the well, hereinafter, the pocket region Pk is not shown in the figure.

As shown in FIG. 5S, after side wall spacers are formed, desired ion implantation is performed in each region, so that a source region S and a drain region D are formed. A Co film or the like is deposited and is then processed by a thermal treatment, so that a silicide layer 18 is formed on the gate, source, and drain.

As shown in FIG. 5T, after each transistor is formed, for example, a silicon nitride film having a thickness of approximately 30 nm and a phosphor silicate glass (PSG) having a thickness of approximately 700 nm are laminated by deposition above the silicon substrate, followed by performing planarization by CMP or the like, so that a first interlayer insulating film 21 having a thickness of approximately 330 nm is formed. A photoresist pattern having apertures of a contact-hole shape is formed on the first interlayer insulating film 21, and by etching thereof, contact holes are formed. A Ti film having a thickness of approximately 10 nm and a TiN film having a thickness of approximately 10 nm, which are used to form a barrier metal, are deposited by sputtering or the like, and a blanket W film having a thickness of approximately 200 nm is then deposited by CVD. An excess metal layer on the first interlayer insulating film 21 is removed by CMP or the like, so that conductive contact plugs 22 are formed.

Subsequently, a multilayer interconnection structure is formed. In the multilayer interconnection structure, a lower side layer has a higher wiring density and is more influenced by a parasitic capacitance. An upper wiring layer has a lower wiring density, and the influence of the parasitic capacitance is also decreased. Hence, demands for individual wiring layers are not the same.

For example, a SiC film having a thickness of approximately 30 nm, a SiOC film having a thickness of approximately 130 nm, and a TEOS silicon oxide film having a thickness of approximately 100 nm are laminated on the first interlayer insulating film 21 having the conductive contact plugs 22, so that a second interlayer insulating film 23 is formed. After trenches penetrating the second interlayer insulating film 23 are formed, a barrier metal layer and a copper layer are formed to be filled therein, and an excess portion is removed by CMP, so that a first copper wiring layer 24 is formed. In this step, the thickness of the insulating film, in particular, of the topmost TEOS silicon oxide film, is the thickness obtained after the first copper wiring layer is formed and is not the thickness obtained by deposition. The thickness of the insulating film described below is the same as described above.

For example, a SiC film having a thickness of approximately 60 nm, a SiOC film having a thickness of approximately 450 nm, and a TEOS silicon oxide film having a thickness of approximately 100 nm are laminated on the second interlayer insulating film 23 to cover the first copper wiring layer 24, so that a third interlayer insulating film 25 is formed. As described above, the thickness indicates the thickness of the insulating film that finally remains. Trenches and via holes are formed in the third interlayer insulating film 25 by a known dual damascene process, and a barrier metal layer and a copper layer are formed, so that a second copper wiring layer 26 is formed. By the same structure and the same process as those described above, fourth to sixth interlayer insulating films 27, 29, and 31, and third to fifth copper wiring layers 28, 30, and 32 are formed.

On the sixth interlayer insulating film 31 provided with the fifth copper wiring layer 32 buried therein, for example, a SiC film having a thickness of approximately 70 nm and a SIOC film having a thickness of approximately 900 nm are laminated, so that a seventh interlayer insulating film 33 is formed. By a dual damascene process, a sixth copper wiring layer 34 is buried in the seventh interlayer insulating film 33. By the same structure and the same process as those described above, an eighth interlayer insulating film 35 and a seventh copper wiring layer 36 are formed.

On the eighth interlayer insulating film 35 provided with the seventh copper wiring layer 36 buried therein, for example, a SiC film having a thickness of approximately 70 nm and a SIOC film having a thickness of approximately 1,500 nm are laminated, so that a ninth interlayer insulating film 37 is formed. In the ninth interlayer insulating film 37, an eighth copper wiring layer 38 is buried by a dual damascene process. By the same structure and the same process as those described above, a tenth interlayer insulating film 39 and a ninth copper wiring layer 40 are formed.

On the tenth interlayer insulating film 39 provided with the ninth copper wiring layer 40 buried therein, for example, a SiC film having a thickness of approximately 70 nm and a SiOC film having a thickness of approximately 800 nm are laminated, so that an eleventh interlayer insulating film 41 is formed. Contact holes are formed in the eleventh interlayer insulating film 41 by etching, a barrier metal and a W layer are filled therein, and an excess portion is then removed by CMP, so that conductive plugs 42 are formed. On the eleventh interlayer insulating film 41 provided with the conductive plugs 42 buried therein, a known Al wire 44 having a thickness of approximately 1.200 nm is formed. A SiO film having a thickness of approximately 1,400 nm and a SiN film having a thickness of approximately 500 nm are laminated to cover the Al wire, so that an insulating film 45 is formed. Subsequently, contact pad windows penetrating the insulating layer 45 are formed over the Al wire. As has thus been described, the multilayer interconnection structure is formed.

Although the present embodiment has been described with reference to the example; however, the present embodiment is not limited thereto. It is to be understood by a person skilled in the art that for example, various modifications, improvements, replacements, combinations, and the like may be made without departing from the spirit and the scope of the present embodiment.

What is claimed is:

1. A method of manufacturing a semiconductor device, comprising:
forming a first insulating film over a rear surface of a plurality of silicon substrates;
annealing the plurality of silicon substrates to degas the oxide species in the first insulating film; and
oxidizing the surface of the plurality of silicon substrates in a batch process after annealing the silicon substrates.

2. The method according to claim 1, wherein the forming a first insulating film is performed by chemical vapor deposition using tetraethoxysilane to form a silicon oxide film as the first insulating film.

3. The method according to claim 1, wherein the forming first insulating film over a rear surface of the plurality of silicon substrates includes forming the first insulating film over the second insulating film over the second insulating film over the front and the rear surface of the silicon substrate, and eliminating the first insulating film over the first insulating film over the surface of the silicon substrate, and exposing the second insulating film;
the method further comprising forming a second insulating film over the front and the rear surface of the silicon substrate, an etching property of the second insulating film being different from the first insulating film, before forming a first insulating film over a rear surface of a plurality of silicon substrates.

4. The method according to claim 3, wherein the second insulating film is a silicon nitride film.

5. The method according to claim 3, wherein the oxidizing the surface of the plurality of silicon substrates in a batch process is processed between eliminating the surface of the silicon substrate using the second insulating film as a mask to form a groove of the shallow trench isolation and forming a shallow trench isolation film filling the groove of the shallow trench isolation, and rounding a corner portion of the active region;
the method further comprising forming an aperture of shallow trench isolation in the second insulating film over the surface of the silicon substrate after eliminating the first insulating film over the first insulating film over the surface of the silicon substrate;
eliminating the surface of the silicon substrate using the second insulating film as a mask to form a groove of the shallow trench isolation defining a plurality of active regions;
forming a shallow trench isolation film filling the groove of the shallow trench isolation; and
chemical mechanical polishing the shallow trench isolation film over the surface of the silicon substrate, using the second insulation film as a stopper;

6. The method according to claim 5, further comprising eliminating the second insulating film over the surface of the silicon substrate after chemical mechanical polishing the shallow trench isolation film after chemical mechanical polishing the shallow trench isolation film over the surface of the silicon substrate, using the second insulation film as a stopper.

7. The method according to claim 5, further comprising forming a flash memory cell on the part of the plurality of active regions.

8. The method according to claim 7, wherein the forming an aperture of shallow trench isolation in the second insulating film over the surface over the silicon substrate further includes forming a photo resist layer over the second insulating layer whose surface is oxidized, exposing and developing the photo resist layer, forming the photo resist layer having an aperture shaped like the groove of shallow trench isolation, forming the second insulating layer by etching using the photo resist layer by as a mask, and eliminating the photo resist layer;
the method further comprising hydrophilizing the surface of the second insulating film after eliminating the first insulating film over the first insulating film over the surface of the silicon substrate and exposing the second film.

9. The method according to claim 8, wherein the hydrophilizing the surface of the second insulating film oxidizes the surface of the silicon nitride film using oxygen plasma, and wherein the annealing the silicon substrate is a dry annealing process in a nitrogen atmosphere.

10. The method according to claim 3, wherein the eliminating the first insulating film over the first insulating film over the surface of the silicon substrate, exposing the silicon nitride film as the second insulating film, and the hydrophilizing the surface of the second insulating film oxidizes the surface of the silicon nitride film by wet oxidation in a nitrogen and oxygen atmosphere, and wherein the annealing the silicon substrate is a dry annealing in a nitrogen atmosphere in a same process chamber.

11. The method according to claim 1, wherein the annealing the plurality of silicon substrates to degas on the oxide species in the first insulating film is processed at over 800 degrees.

12. The method according to claim 1, wherein the oxidizing the surface of the plurality of silicon substrates in a batch process after annealing the silicon substrate is processed in a dry oxidization at over 1000 degrees.

13. The method according to claim 5, wherein the oxidizing the surface of the plurality of silicon substrates in a batch process after annealing the silicon substrate is a rounding oxidation at the corner of the active region, the corner having a curvature radius ranging from 4 nm to 30 nm.

14. The method according to claim 7, further comprising forming a metal oxide semiconductor at a part of an active region other than the active region where the flash memory cell region is formed.
